(19) United States
(12) Patent Application Publication
(10) Pub. No.: US 2025/0033082 A1
(43) Pub. Date: Jan. 30, 2025

(54) METHOD AND COMPOSITION FOR REDUCING SOLVENT RELEASE FROM, AND REDUCING ODOR OF, AGROCHEMICAL FORMULATIONS

(71) Applicant: Adama Makhteshim Ltd., Beer Sheva (IL)

(72) Inventors: Ivan Gorlovetsky, Beer Sheva (IL); Alexey Utsis, Beer Sheva (IL); Micha Mosco, Yehud (IL)

(73) Assignee: Adama Makhteshim Ltd., Beer Sheva (IL)

(21) Appl. No.: 18/704,436

(22) PCT Filed: Oct. 24, 2022
(86) PCT No.: PCT/IB2022/060208

§ 371 Date: Apr. 24, 2024

Related U.S. Application Data
(60) Provisional application No. 63/271,419, filed on Oct. 25, 2021.

(51) Int. Cl. B05D 1/00

(52) U.S. Cl. CPC B05D 1/62; B05D 2201/02

(57) ABSTRACT

The present invention provides a method of preventing leakage of an aromatic compound from an article containing a formulation comprising the aromatic compound and a polar liquid, wherein the method comprises plasma-coating the article.

This application claims the benefit of U.S. Provisional Application No. 63/271,419, filed Oct. 25, 2021, the entire contents of each of which are hereby incorporated by reference into the subject application.

### TECHNICAL FIELD

This invention relates to use of plasma coated articles to prevent leakage of aromatic compounds.

### BACKGROUND OF THE INVENTION

Regular types of packaging made of polymer material such as high-density polyethylene (HDPE) and coextruded (OEX) material show a strong odor of certain formulations comprising aromatic compound(s), such as emulsion-in-water composition comprising acetophenone, which suggest leakage of the aromatic compound from the packaging material. Such leakage pollutes the environment. Polymer materials are light, flexible, strong, less costly and easier to implement compared to metals or glass. Unfortunately, their barrier properties with respect to the diffusion of aromatic compounds such as acetophenone is in general poor compared to those of metals and glass. This is in particular true for the polymers most used in the packaging industry such as PE (polyethylene), PP (polypropylene) PET (polyethylene terephthalate), or HDPE (High Density Polyethylene).

Moreover, on account of diffusion phenomena, aromatic compounds such as acetophenone can migrate slowly and continuously from the inside of the article made of polymer material to the outside by crossing the wall of said article made of polymer material and in this way spreading into the environment.

During this migration, a more-or-less significant portion of the aromatic compound such as acetophenone is trapped, thus increasing the initial weight of the article made of polymer material. The variation in weight may be of several percent and, over time, the wall of the article made of polymer material swells and its chemical composition changes.

### SUMMARY OF INVENTION

The present invention provides a method of preventing leakage of an aromatic compound from an article containing a formulation comprising an aromatic compound and a polar liquid or a non-polar liquid, wherein the method comprises plasma-coating the article.

In some embodiments, the formulation comprising the aromatic compound and the polar liquid is an emulsion-in-water (EW) formulation.

In some embodiments, the formulation further comprising the aromatic compound with macrocyclic lactones endectocides.

In some embodiments the macrocyclic lactones endectocides is abamectin.

In some embodiments, the formulation further comprising the aromatic compound and the non-polar liquid is an emulsifiable-concentrate (EC) formulation.

In some embodiments, the formulation further comprising the aromatic compound with a non-polar liquid and optionally mixed with a polar liquid as a co-solvent.

In some embodiments, the formulation further comprising the aromatic compound with a triazole fungicide with a non-polar liquid and optionally mixed with a polar liquid as a cosolvent.

In some embodiments, the triazole fungicide is prothioconazole.

In some embodiments, the aromatic compound is acetophenone.

In some embodiments, the polar liquid is water.

In some embodiments, the article is made of a polymer material.

In some embodiment, the article is made of polymer material selected from the group consisting of a polyethylene, a high-density polyethylene (HDPE), a polypropylene, a polyamide, a PET, a vinyl polychloride, polycarbonate, poly butyl teraphtalate and combinations thereof.

The present invention provides a plasma-coated article containing a formulation comprising an aromatic compound and a polar liquid or a non-polar liquid.

The present invention provides use of a plasma-coated article for containing a formulation comprising an aromatic compound and a polar liquid or a non-polar liquid to prevent leakage of the aromatic compound from the article.

The present invention provides a process for manufacturing the article which comprising plasma coating the article and filling the article with a formulation comprising an aromatic compound and a polar liquid or a non-polar liquid.

The present invention provides a process for making the article which comprises obtaining a plasma coated article and filling the article with a formulation comprising an aromatic compound and a polar liquid or a non-polar liquid.

The present invention provides use of a plasma-coated article for containing an emulsion-in-water (EW) formulation comprising an aromatic compound and water to prevent leakage of the aromatic compound from the article.

The present invention provides use of a plasma-coated article for containing an emulsifiable-concentrate (EC) formulation comprising an aromatic compound, non-polar liquid and optionally mixed with a polar liquid as a co-solvent to prevent leakage of the aromatic compound from the article.

The present invention provides use of a plasma-coated article for storing an emulsion-in-water (EW) formulation comprising acetophenone and water to prevent leakage of acetophenone from the article.

The present invention provides use of a plasma-coated article for storing an emulsifiable-concentrate (EC) formulation comprising acetophenone, prothioconazole and optionally mixed with a polar liquid as a co-solvent to prevent leakage of the aromatic compound from the article.

### DESCRIPTION OF FIGURE

FIG. 1 shows the apparatus described in U.S. Publication No. 2014/0255676 for producing layers on an article. The apparatus 1 for producing the coating according to the invention comprises a support plate 2 overcoated by a radiofrequency faraday shield 3 having a radiofrequency electrode 5 supported by isolation means 6 provided on the support plate 2. The electrode 5 is connected to a radiofrequencies generator 4, known as such.

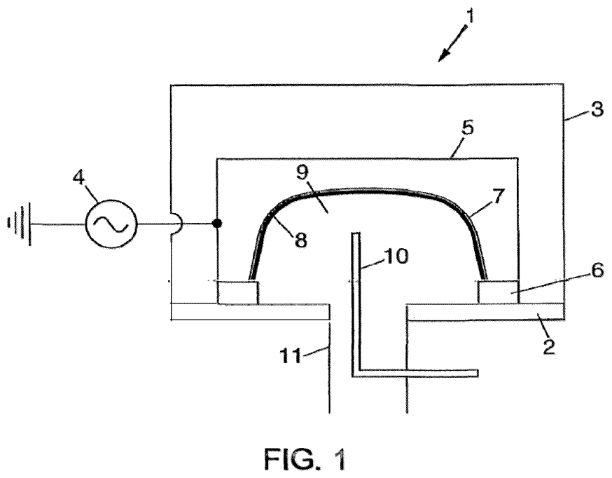

The electrode 5 has an internal shaped wall 7 on which the article to be coated 8 is placed. Advantageously, the internal shaped wall 7 has a complementary form of the form of article 8. The article to be coated 8 forms an internal volume 9 which is the reacting chamber in which gas from an inlet 10, is injected.

Pumping means are also provided in order to reduce, the pressure inside the internal volume through an aperture 11 in the support plate 2.

Pressure is gradually reduced inside the reaction chamber 9 to a value of around 0.01 mbar. Reaction gases are then introduced through the gas inlet 10 in the reaction chamber 9 until a pressure of about 0.1 mbar.

Then an electrical glow discharge is applied through the electrode 5 disposed around the article closely to its external surface so that the plasma is generated only on the inner surface of the article 8.

### DETAIL DESCRIPTION OF INVENTION

### Definitions

Unless defined otherwise, all technical and scientific terms used herein have the meaning commonly understood by persons of ordinary skill in the art to which this subject matter pertains.

Throughout the application, descriptions of various embodiments use the term “comprising”; however, it will be understood by one of skill in the art, that in some specific instances, an embodiment can alternatively be described using the language “consisting essentially of” or “consisting of.”

As used herein, the term “a” or “an” includes the singular and the plural, unless specifically stated otherwise. Therefore, the terms “a,” “an” or “at least one” can be used interchangeably in this application.

As used herein, the term “about” when used in connection with a numerical value includes ±10% from the indicated value. In addition, all ranges directed to the same component or property herein are inclusive of the endpoints, are independently combinable, and include all intermediate points and ranges. It is understood that where a parameter range is provided, all integers within that range, and tenths thereof, are also provided by the invention. For example, “10-40%” includes 10.1%, 10.2%, 10.3%, etc. up to 40%.

As used herein, the term “and/or” includes any and all combinations of one or more of the associated listed items. Expressions such as “at least one of,” when preceding a list of elements, modify the entire list of elements and do not modify the individual elements of the list.

As used herein, the term “thin film” means a film with a thickness less than a few hundreds of nanometers.

As used herein, “alkyl” is intended to include both branched and straight-chain saturated aliphatic hydrocarbon groups having the specified number of carbon atoms. Thus, C1-Cn as in “C1-Cn alkyl” is defined to include groups having 1, 2 . . . n−1 or n carbons in a linear or branched arrangement, and specifically includes methyl, ethyl, propyl, butyl, pentyl, hexyl, heptyl, isopropyl, isobutyl, sec-butyl and so on. An embodiment can be C₁-C₁₂ alkyl, C₂-C₁₂ alkyl, C₃-C₁₂ alkyl, C₄-C₁₂ alkyl and so on. An embodiment can be C₁-C₈ alkyl, C₂-C₈ alkyl, C₃-C₈ alkyl, C₄-C₈ alkyl and so on.” alkoxy” represents an alkyl group as described above attached through an oxygen bridge.

As used herein, “plasma treatment” means the chemical decomposition of a gaseous compound by an electrical glow discharge under reduced atmosphere.

As used herein, “rigid” means an article whose wall has a thickness of at least one mm.

The present invention provides a method of preventing leakage of an aromatic compound from an article containing a formulation comprising the aromatic compound and a polar liquid or a non-polar liquid, wherein the method comprises plasma-coating the article.

The present invention provides use of a plasma-coated article for containing a formulation comprising an aromatic compound and a polar liquid or a non-polar liquid to prevent leakage of the aromatic compound.

In some embodiments, the plasma-coated article is used to store the formulation comprising an aromatic compound and a polar liquid or a non-polar liquid to prevent leakage of the aromatic compound.

In some embodiments, the formulation is an emulsion-in-water (EW).

In some embodiments, the formulation further comprising the aromatic compound with macrocyclic lactones endectocides.

In some embodiments, macrocyclic lactones endectocides is abamectin, doramectin, eprinomectin, ivermectin, milbemycin, moxidectin, or selamectin.

In some embodiments, the macrocyclic lactones endectocides is abamectin.

In some embodiments, the formulation further is an emulsifiable-concentrate (EC) formulation.

In some embodiments, the formulation further comprising the aromatic compound with a non-polar liquid and optionally mixed with a polar liquid as a co-solvent.

In some embodiments, the formulation further comprising the aromatic compound with a triazole fungicide with a non-polar liquid and optionally mixed with a polar liquid as a co-solvent.

In some embodiments, triazole fungicide is cyproconazole, flusilazole, flutriafol, metconazole, myclobutanil, propiconazole, prothioconazole, tebuconazole, or tetraconazole. In some embodiments, the triazole fungicide is prothioconazole.

In some embodiments, wherein the non-polar liquid is Aromatic solvent C10 (Solvesso™ 150), Solvent Naphtha (Petroleum), Light Aromatic (Solvesso™ 100), Aromatic solvent C12 (Solvesso™ 200), cyclohexanone, isophorone, methyl ethyl ketone, methyl iso butyl ketone, acetophenone, xylene, methyl soyate, Rapeseed oil methyl ester (Agnique® ME 18RD-F), paraffinic oils, rapeseed oil, soybean oil, dimethylamide based on naturally derived fatty acids (Genagen® 4296), 2-ethylhexyl-1-lactate (Purasolv® EH), dimethylamide based on naturally derived fatty acids (Genegen® 4166), unsaturated di-substituted amide (Steptosol® MET10U), C8-10 Methyl Caprylate-Caprate (Agnique® ME 610-G), N-octyl pyrrolidone (Agsolex™-8), or N-dodecyl pyrrolidone (Agsolex™-12).

In some embodiments, the polar liquid is water, methyl 5-(dimethylamino)-2-methyl-5-oxopentanoate (Rhodiasolv® Polar Clean), N,N-dimethyl lactamide (Agnique® AMD 3 L), morpholine/carbonate blend (Armid™ FMPC), propylene carbonate, n-butylpyrrolidone, (Genagen NBPTM), DMSO, DMF, NMP, ethyl lactate, PEG 200, butyrolactone, THFA, propylene glycol, butanol, dipropylene glycol, or methyl lactate.

In some embodiments, the polar liquid is water.

In some embodiments, the aromatic compound is an aromatic ketone.

In some embodiment, the aromatic compound is selected from the group consisting of 3′,5′-dimethoxyacetophenone, raspberry ketone, acetophenone, benzophenone, 4′-methylacetophenone, benzylacetone, 4-(4-methoxyphenyl)-2-butanone, piperonyl acetone, 4′-methoxyacetophenone, dimedone, thenoyltrifluoroacetone, 4′-fluoropropiophenone, 1,3-diphenylacetone, n-(2-benzoyl-4-chlorophenyl)-2-chloro-n-methylacetamide, 4-chlorophenylacetone, 4-hydroxyphenylacetone, 4′-bromo-3′-nitroacetophenone, cyclopentyl phenyl ketone, (+)-pulegone, 4,4-diphenyl-2-butanone, 3,4-dihydroxyphenylacetone, (3-(trifluoromethoxy)phenyl) acetone, 4′-chloro-2 phenylacetophenone, 4-hydroxy-3-methoxyphenylacetone, 3-tetradecanone, 4-(4-hydroxy-3-methoxyphenyl)-3-buten-2-one, indole-3-acetone, 2-chloro-6-fluorophenylacetone, 3,4-(methylenedioxy) benzylideneacetone, 4′-aminobutyrophenone, 4-ethylphenylacetone, 4′-methyl-2-phenylacetophenone, n-tetradecanophenone, 4′-methoxy-2-phenylacetophenone, 2,6-dichlorophenylacetone,2,5-dimethylphenylacetone, zearalenone, 3,4,5-trimethoxyphenylacetone, 14-heptacosanone, 2-bromo-1-(3-bromophenyl)-1-propanone, nootkatone (sg), 4-methylphenylacetone, piperonyl methyl ketone, 10-nonadecanone, (4-carboxyphenyl) acetone, 4,4′-dibromobenzil, 3-methylphenylacetone, 4-hydroxybenzylideneacetone, 4-nitrophenylacetone, 3-chlorophenylacetone, 2,6-difluorophenylacetone, 3-methoxyphenylacetone, 1-acetamido-acetone, 1,3-dibromoacetone, (2,4-dimethoxyphenyl) acetone, and any combination thereof. In some embodiment, the aromatic compound has the following structure:

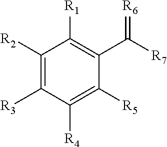

wherein R₁, R₂, R₃, R₄, R₅ is each hydrogen, C₁₋₆ alkyl, C₁₋₆ alkoxy, phenyl, benzyl, or halogen;
wherein R₆ is O or S;
wherein R₇ is each hydrogen, CH₂NO₂, C₁₋₆ alkyl, C₁₋₆ alkoxy, phenyl, benzyl, or halogen.

In some embodiments, the aromatic ketone is acetophenone.

In some embodiments, the formulation comprises from about 10% to about 40% by weight of aromatic compound based on the total weight of the formulation.

In some embodiments, the formulation comprises from about 20% to about 30% by weight of aromatic compound based on the total weight of the formulation.

In some embodiments, the formulation comprises about 20% by weight of aromatic compound based on the total weight of the formulation.

In some embodiments, the formulation of aromatic compound is stored in the plasma coated article for a period over 8-15 days.

In some embodiments, the formulation of aromatic compound is stored in the plasma coated article for a period over 11 days.

In some embodiments, the formulation of aromatic compound is stored at about 25-70° C.

In some embodiments, the formulation of aromatic compound is stored at about 40-65° C.

In some embodiments, the formulation of aromatic compound is stored at about 52-60° C.

In some embodiments, the formulation of aromatic compound is stored at about 54° C.

In some embodiments, after storing the formulation comprising the aromatic compound in the plasma coated article for 11 days at 54° C., more than 80% by weight of the aromatic compound remain in the formulation.

In some embodiments, after storing the formulation comprising the aromatic compound in the plasma coated article for 11 days at 54° C., more than 85% by weight of the aromatic compound remain in the formulation.

In some embodiments, after storing the formulation comprising the aromatic compound in the plasma coated article for 11 days at 54° C., more than 90% by weight of the aromatic compound remain in the formulation.

In some embodiments, after storing the formulation comprising the aromatic compound in the plasma coated article for 11 days at 54° C., more than 95% by weight of the aromatic compound remain in the formulation.

In some embodiments, after storing the formulation comprising the aromatic compound in the plasma coated article for 11 days at 54° C., more than 99% by weight of the aromatic compound remain in the formulation.

In some embodiments, the article containing the formulation is stored for at least 10-20 days.

In some embodiments, the article containing the formulation is stored for at least 12-18 days.

In some embodiments, the article containing the formulation is stored for 14 days.

In some embodiments, the article containing the formulation is stored for at least 10-20 days at room temperature.

In some embodiments, the article containing the formulation is stored for at least 12-18 days at room temperature.

In some embodiments, the article containing the formulation is stored for 14 days at room temperature.

In some embodiments, the article containing the formulation is stored for at least 10-20 days at room temperature, wherein the article is HDPE Plasma with aluminum pouch.

In some embodiments, the article containing the formulation is stored for at least 12-18 days at room temperature, wherein the article is HDPE Plasma with aluminum pouch.

In some embodiments, the article containing the formulation is stored for 14 days at room temperature, wherein the article is HDPE Plasma with aluminum pouch.

In some embodiments, the article containing the formulation is stored for at least 10-20 days at room temperature, t wherein he article is Co-Ex-PA with aluminum pouch.

In some embodiments, the article containing the formulation is stored for at least 12-18 days at room temperature, wherein the article is Co-Ex-PA with aluminum pouch.

In some embodiments, the article containing the formulation is stored for 14 days at room temperature, wherein the article is Co-Ex-PA with aluminum pouch.

In some embodiments, the article containing the formulation is HDPE Plasma with aluminum pouch.

In some embodiments, the article containing the formulation is Co-Ex-PA with aluminum pouch.

In some embodiments, 0% of the aromatic compound was leaked.

In some embodiments, the article containing the formulation is stored for at least 10-20 days at a temperature of at least 45-60° C.

In some embodiments, the article containing the formulation is stored for at least 10-20 days at a temperature of at least 50-55° C.

In some embodiments, the article containing the formulation is stored for at least 10-20 days at a temperature of at 54° C.

In some embodiments, the article containing the formulation is stored for at least 12-18 days at a temperature of at least 45-60° C.

In some embodiment, the article containing the formulation is stored for at least 12-18 days at a temperature of at least 50-55° C.

In some embodiment, the article containing the formulation is stored for at least 12-18 days at a temperature of at 54° C.

In some embodiments, the article containing the formulation is stored for 14 days at a temperature of at least 45-60° C.

In some embodiments, the article containing the formulation is stored for 14 days at a temperature of at least 50-55° C.

In some embodiments, the article containing the formulation is stored for 14 days at a temperature of 54° C.

In some embodiments, the article containing the formulation is stored for at least 10-20 days at a temperature of at least 45-60° C., wherein the article is HDPE Plasma with aluminum pouch.

In some embodiments, the article containing the formulation is stored for at least 10-20 days at a temperature of at least 50-55° C., wherein the article is HDPE Plasma with aluminum pouch.

In some embodiments, the article containing the formulation is stored for at least 10-20 days at 54° C., wherein the article is HDPE Plasma with aluminum pouch.

In some embodiments, the article containing the formulation is stored for at least 12-18 days at a temperature of at least 45-60° C., wherein the article is HDPE Plasma with aluminum pouch.

In some embodiments, the article containing the formulation is stored for at least 12-18 days at a temperature of at least 50-55° C., wherein the article is HDPE Plasma with aluminum pouch.

In some embodiments, the article containing the formulation is stored for at least 12-18 days at 54° C., wherein the article is HDPE Plasma with aluminum pouch.

In some embodiments, the article containing the formulation is stored for 14 days at a temperature of at least 45-60° C., wherein the article is HDPE Plasma with aluminum pouch.

In some embodiments, the article containing the formulation is stored for 14 days at a temperature of at least 50-55° C., wherein the article is HDPE Plasma with aluminum pouch.

In some embodiments, the article containing the formulation is stored for 14 days at 54° C., wherein the article is HDPE Plasma with aluminum pouch.

In some embodiments, the article containing the formulation is stored for at least 10-20 days at a temperature of at least 45-60° C., wherein the article is Co-Ex-PA with aluminum pouch.

In some embodiments, the article containing the formulation is stored for at least 10-20 days at a temperature of at least 50-55° C., wherein the article is Co-Ex-PA with aluminum pouch.

In some embodiments, the article containing the formulation is stored for at least 10-20 days at 54° C., wherein the article is Co-Ex-PA with aluminum pouch.

In some embodiments, the article containing the formulation is stored for at least 12-18 days at a temperature of at least 45-60° C., wherein the article is Co-Ex-PA with aluminum pouch.

In some embodiments, the article containing the formulation is stored for at least 12-18 days at a temperature of at least 50-55° C., wherein the article is Co-Ex-PA with aluminum pouch.

In some embodiments, the article containing the formulation is stored for at least 12-28 days at 54° C., wherein the article is Co-Ex-PA with aluminum pouch.

In some embodiments, the article containing the formulation is stored for 14 days at a temperature of at least 45-60° C., wherein the article is Co-Ex-PA with aluminum pouch.

In some embodiments, the article containing the formulation is stored for 14 days at a temperature of at least 50-55° C., wherein the article is Co-Ex-PA with aluminum pouch.

In some embodiments, the article containing the formulation is stored for 14 days at 54° C., wherein the article is Co-Ex-PA with aluminum pouch.

In some embodiments, the article containing the formulation is HDPE Plasma with aluminum pouch.

In some embodiments, the article containing the formulation is Co-Ex-PA with aluminum pouch

In some embodiments, more than 50% by weight of the aromatic compound remain in the formulation.

In some embodiments, more than 60% by weight of the aromatic compound remain in the formulation.

In some embodiments, more than 66.6% by weight of the aromatic compound remain in the formulation.

In some embodiments, after storing the emulsion-in-water (EW) formulation comprising acetophenone in the plasma coated article for 11 days at 54° C., more than 80% by weight of the acetophenone remain in the formulation.

In some embodiments, after storing the emulsion-in-water (EW) formulation of acetophenone in the plasma coated article for 11 days at 54° C., more than 85% by weight of the acetophenone remain in the formulation.

In some embodiments, after storing the emulsion-in-water (EW) formulation of acetophenone in the plasma coated article for 11 days at 54° C., more than 90% by weight of the acetophenone remain in the formulation.

In some embodiments, after storing the emulsion-in-water (EW) formulation of acetophenone in the plasma coated article for 11 days at 54° C., more than 95% by weight of the acetophenone remain in the formulation.

In some embodiments, after storing the emulsion-in-water (EW) formulation of acetophenone in the plasma coated article for 11 days at 54° C., more than 99% by weight of the acetophenone remain in the formulation.

In some embodiments, after storing the emulsifiable-concentrate (EC) formulation comprising acetophenone in the plasma coated article for 10-11 days at 54° C., more than 80% by weight of the acetophenone remain in the formulation.

In some embodiments, after storing the emulsifiable-concentrate (EC) formulation of acetophenone in the plasma coated article for 10-11 days at 54° C., more than 85% by weight of the acetophenone remain in the formulation.

In some embodiments, after storing the emulsifiable-concentrate (EC) formulation of acetophenone in the plasma coated article for 10-11 days at 54° C., more than 90% by weight of the acetophenone remain in the formulation.

In some embodiments, after storing the emulsifiable-concentrate (EC) formulation of acetophenone in the plasma coated article for 10-11 days at 54° C., more than 95% by weight of the acetophenone remain in the formulation.

In some embodiments, after storing the emulsifiable-concentrate (EC) formulation of acetophenone in the plasma coated article for 10-11 days at 54° C., more than 99% by weight of the acetophenone remain in the formulation.

In some embodiments, the article is one or more of a container, a bottle, a canister and a bucket.

In some embodiment, the article is made of polymer material selected from the group consisting of a polyethylene, a high-density polyethylene (HDPE), a polypropylene, a polyamide, a PET, a vinyl polychloride, polycarbonate, poly butyl teraphtalate and combinations thereof.

In some embodiments, the article is made of polyethylene.

In some embodiments, the article is made of a high-density polyethylene (HDPE).

In some embodiments, the article is made of a polypropylene.

In some embodiments, the article is made of polyamide.

In some embodiments, the article is made of polyethylene terephthalate (PET).

In some embodiments, the article is made of vinyl polychloride.

In some embodiments, the article is made of polycarbonate.

In some embodiments, the article is made of poly butyl teraphtalate.

In some embodiments, the plasma is one or more of tetrafluoroethane-1, 1, 1, 2, argon, acetylene, pentafluoroethane, difluoromethane or SiOxCyHz wherein x is between 0 and 1.7, y is between 0.5 and 0.8, and z is between 0.35 and 0.6.

In some embodiments, the plasma is tetrafluoroethane-1, 1, 1, 2.

In some embodiments, the plasma is acetylene.

In some embodiments, the plasma is argon.

In some embodiments, the plasma is pentafluoroethane. In some embodiment, the plasma is difluoromethane.

In some embodiments, the plasma is SiOxCyHz wherein x is between 0 and 1.7, y is between 0.5 and 0.8, and z is between 0.35 and 0.6.

In some embodiments, the plasma is SiOxCyHz wherein x is between 1.7 and 1.99, y is between 0.2 and 0.7, and z is between 0.2 and 0.35.

In some embodiments, the present invention provides a container containing a formulation comprising an aromatic compound and a polar liquid or a non-polar liquid.

In some embodiments, the present invention provides a process for manufacturing the article of comprising plasma coating the article and filling the article with a formulation comprising an aromatic compound and a polar liquid or a non-polar liquid.

### Method of Plasma Coating The Article

This section details the method of plasmas coating an article, specifically a container. The method discussed in this section is the method disclosed in International Publication No. WO 2020/148487, U.S. Patent Publication Nos. 2008/0081129 and 2014/0255676.

The entire content of U.S. Patent Publication Nos. US 2008/0081129, and US2014/0255676 is hereby incorporated by reference into this application.

In some embodiment, the method comprises plasma-coating the article by depositing a coating with a barrier effect on at least one surface of the article, preferably made of polymer material.

In some embodiments, the method comprises:
depositing a first deposit layer with a discharge plasma in acetylene gas at low pressure; and
   a. depositing a second deposit layer with a discharge plasma in at least one of tetrafluoroethane-1, 1, 1,2 or pentafluoroethane precursor gas, wherein deposition of the first deposit layer and second deposit layer comprises:
   b. introducing the article made of polymer material into a treatment chamber;
   c. introducing at least one precursor gas into the treatment chamber;
   d. applying one of electrical energy or electromagnetic energy of a sufficient space density power and a sufficient frequency to bring the at least one gas to a plasma state; and subjecting the article made of polymer material to the plasma state for a sufficient plasma phase time so as to deposit one of the first deposit layer or second deposit layer.

In some embodiment, an electrical or electromagnetic energy is applied during deposition such that the space density of power is in a range from about 0.01 W/cm³ to about 10 W/cm³.

In some embodiment, an electrical or electromagnetic energy is applied during deposition such that the space density of power is in a range from about 0.1 W/cm³ to about 3 W/cm³.

In some embodiment, frequency was selected during deposition from the group consisting of 40 kHz, 13.56 MHz, and 2,450 MHz.

In some embodiment, the plasma phase was maintained for a time in a range from about 1 second to about 2 minutes.

In some embodiment, the plasma phase was maintained for a time in a range from about 1 second to about 30 seconds.

In some embodiment, at least one precursor gas was introduced into the treatment chamber at a flow rate such that a pressure inside the treatment chamber is in a range from about 0.002 mbar to about 10 mbar.

In some embodiment, at least one precursor gas was introduced into the treatment chamber at a flow rate such that a pressure inside the treatment chamber is in a range from about 0.01 mbar to about 1 mbar.

In some embodiment, the method comprises a preparation step and the preparation step is comprised of:
a. preparing at least one surface of the article made of polymer material prior to depositing the first and second deposit layers, the method of preparing comprising:
   i. implementing a low pressure discharge plasma in at least one gas selected from the group consisting of oxygen, hydrogen, argon, carbon dioxide, helium, nitrogen, and combinations thereof by:
   ii. introducing the at least one gas into the treatment chamber;
b. applying one of electrical energy or electromagnetic energy of a sufficient space density power and a sufficient frequency to bring the at least one gas to a plasma state; and subjecting the article made of polymer material to the plasma state for a sufficient plasma phase time to prepare the at least one surface.

In some embodiment, a low pressure discharge plasma from a mixture of argon and hydrogen was implemented, with a pressure in a range from about 0.01 mbar to about 5 mbar.

In some embodiment, a low pressure discharge plasma from a mixture of argon and hydrogen was implemented, with a pressure in a range from about 0.05 mbar to about 1 mbar.

In some embodiment, an electrical or electromagnetic energy is applied during deposition such that the space density of power is in a range from about 0.01 W/cm³ to about 10 W/cm³.

In some embodiment, an electrical or electromagnetic energy is applied during deposition such that the space density of power is in a range from about 0.1 W/cm³ to about 3 W/cm³.

In some embodiment, the plasma phase was maintained for a time in a range from about 1 second to about 30 seconds.

In some embodiment, a third deposit layer was deposited with a low pressure discharge plasma in acetylene or pentafluoroethane gas.

In some embodiment, the article made of polymer material was in the form of a substantially open hollow article.

In some embodiment, the article made of polymer material comprises a substantially open hollow article of high density polyethylene and wherein the internal pressure within the article is less than about 0.05 mbar and the external pressure is about 30 mbar, and wherein the precursor comprises a mixture of argon and hydrogen gases, the method further comprising:
a. introducing the mixture of argon and hydrogen gas within the treatment chamber at a flow rate such that the internal pressure is in a range of about 0.05 and 1 mbar;
b. applying microwave energy with a power of about 200 W to form a plasma;
c. subjecting the article to the plasma for a duration of about 6 seconds;
d. and turning off the microwave energy and the flow of the mixture of argon and hydrogen gas.

In some embodiment, a first deposit layer was deposited with a discharge plasma in acetylene gas at low pressure comprises:
a. introducing the acetylene gas to the treatment chamber at a flow rate such that the internal pressure is in a range of about 0.05 and 0.3 mbar;
b. applying microwave energy with a power of about 300 W to form a plasma;
c. subjecting the article to the plasma for a duration of about 1 second;
d. and turning off the microwave energy and the flow of the acetylene gas.

In some embodiment, a second deposit layer was deposited with a discharge plasma in at least one of tetrafluoroethane-1,1,1,2 or pentafluoroethane precursor gas comprises:
a. introducing the acetylene gas to the treatment chamber at a flow rate such that the internal pressure is in a range of about 0.05 and 0.3 mbar;
b. applying microwave energy with a power of about 300 W to form a plasma;
c. subjecting the article to the plasma for a duration of about 6 seconds; a
d. and turning off the microwave energy and the flow of the precursor gas.

In some embodiment, a polymer article is comprised of:
a. a thin coating on at least one side of said article;
b. a polymer material defining a supporting surface of the polymer article; wherein said thin coating directly covers the supporting surface;
   wherein said thin coating comprises an outer coating of SiOxCyHz defining an outer surface of the polymer article, the outer coating of SiOxCyHz being a plasma polymerized tetramethylsilane and an oxidizing gas, wherein x is between 1.7 and 1.99, y is between 0.2 and 0.7, and z is between 0.2 and 0.35, for said outer SiOxCyHz coating; and
   wherein the thickness of said outer coating is from about 10 nanometers to about 100 nanometers.

In some embodiment, the thin coating comprises a first coating of SiOxCyHz which is either a plasma polymerized tetramethylsilane or a plasma polymerized tetramethylsilane and an oxidizing gas, deposited on the supporting surface on said polymer article, and wherein the outer coating of SiOxCyHz is a second coating of SiOxCyHz deposited on the surface on said first coating.

In some embodiment, x is between 0 and 1.7, y is between 0.5 and 0.8, and z is between 0.35 and 0.6 for said first SiOxCyHz coating, the first coating and the second coating defining said thin coating.

In some embodiment, the thickness of said first coating is from about 1 nanometer to about 15 nanometers.

In some embodiment, the thickness of said second coating is from 15 nanometers to 50 nanometers. In some embodiment, the thickness of said second coating is 30 nanometers.

In some embodiment, the value of x for said first SiOxCyHz coating is less than a value of x for said second SiOxCyHz coating, and a value of z for said first SiOxCyHz coating is greater than a value of z for said second SiOxCyHz coating.

In some embodiment, the supporting surface is an inner surface of a three-dimensional article.

In some embodiment, said outer coating defines the thin coating and is directly deposited on said supporting surface.

In some embodiment, the coating on the polymer material is obtained at low pressure from a gaseous plasma of tetrafluoroethane-1,1,1,2 (C₂H₂F₄, or H₂FC—CF₃), a mixture conventionally designated by the name HFC R134a.

In some embodiment, the coating on the polymer material is obtained at low pressure from a gaseous plasma of pentafluoroethane (C₂HF₅ or HF₂C—CF₃), a product conventionally designated under the name HFC R125.

In some embodiment, the polymer article with a plasma coating has a reduced tendency of being stained.

In some embodiment, the polymer article with a plasma coating according to the present invention is not washed out in a dishwasher.

In some embodiment, the plasma coating has a good steam-resistance.

In some embodiment, the plasma coating has a good adhesion on a polymer article with no detachment.

In some embodiment, the plasma article remains transparent after several washes.

In some embodiment, the plasma article incorporating a plasma coating with a reduced wall thickness while maintaining a suitable barrier to the permeation of odorants, flavorants, ingredients, gas and water vapor.

In some embodiment, the plasma gas is stable and does not react when in contact with oxygen.

In some embodiment, the plasma gas has a sufficient saturation vapor pressure in order to be moved from a storage place to a reacting chamber without adding a carrier gas.

In some embodiment, the plasma gas does not need to be heated during its moving from a storage place to a reacting chamber in order to avoid the condensation of said reacting gas.

In some embodiment, the plasma gas does not have the chemical property of spontaneous combustion.

In some embodiment, the polymer article having a thin coating on at least one of its side, characterized in that said coating comprises a first coating of SiOxCyHz which is either a plasma polymerized tetramethylsilane or a plasma polymerized tetramethylsilane and an oxidizing gas, preferentially oxygen or carbon dioxide, deposited on the surface on said polymer article, the x value being between 0 and 1.7, the y value being between 0.5 and 0.8, the z value being between 0.35 and 0.6 for said first SiOxCyHz coating and a second coating of SiOxCyHz which is a plasma polymerized tetramethylsilane and an oxidizing gas, preferentially oxygen or carbon dioxide, deposited on the surface on said first coating, the x value being between 1.7 and 1.99, the y value being between 0.2 and 0.7, the z value being between 0.2 and 0.35 for said second SiOxCyHz coating and in that the thickness of said first coating is from about 1 nanometer to about 15 nanometers and in that the thickness of said second coating is from about 10 nanometers to about 100 nanometers, preferentially around 30 nanometers.

In some embodiment, the method for manufacturing a polymer article having a thin coating formed on at least one of its side by plasma, characterized in that said method comprises successively:
a) a plasma treatment on said polymer article, advantageously an argon plasma treatment;
b) a deposition of a first coating of SiOxCyHz by generation of a plasma either from tetramethylsilane, or from tetramethylsilane and an oxidizing gas, preferentially oxygen or carbon dioxide, the x value being between 0 and 1.7, the y value being between 0.5 and 0.8, the z value being between 0.35 and 0.6 for said first SiOxCyHz coating, and
c) a subsequent deposition of a second coating of SiOxCyHz by generation of a plasma from tetramethylsilane in the presence of an oxidizing gas, preferentially oxygen 02 or carbon dioxide CO2, the x value being between 1.7 and 1.99, the y value being between 0.2 and 0.7, the z value being between 0.2 and 0.35 for said second SiOxCyHz coating, the thickness of said first, coating being from about 1 nanometer to about 15 nanometers and the thickness of said second coating being from about 10 nanometers to about 100 nanometers, preferentially around 30 nanometers.

In some embodiment, the oxygen percentage in the coating is controlled as the tetramethylsilane does not contain any oxygen element.

In some embodiment, the oxygen percentage in the coating layer is only controlled by the flow of the oxidizing gas.

In some embodiment, the tetramethylsilane is used without adding a carrier gas between a storage place to the reacting chamber.

In some embodiment, the coating is made using either magnetic guidance, or a plasma generating electrode, or both magnetic guidance and a plasma generating electrode.

In some embodiment, power is loaded to the plasma using a frequency of 13.56 MHz.

In some embodiment, the ratio between oxygen and tetramethylsilane is between around zero and four so as to obtain said first coating, said ratio being between around four and ten so as to obtain said second coating onto said first one.

In some embodiment, the ratio between oxygen and tetramethylsilane is maintained during a first step of around one to four seconds at its first value of around zero to four, said ratio being maintained during a second step of around five to thirty seconds at its second value of around four to ten.

In some embodiment, a 3D polypropylene article is placed in a vacuum chamber thus defining an internal volume, the internal volume forming the reaction chamber for the plasma treatment.

In some embodiment, pumping means are also provided in order to reduce the pressure inside the internal volume through an aperture 11 in the support plate 2.

In some embodiment, pressure is gradually reduced inside the reaction chamber 9 to a value of around 0.01 mbar. Reaction gases are then introduced through the gas inlet 10 in the reaction chamber 9 until a pressure of about 0.1 mbar.

In some embodiment, an electrical glow discharge is applied through the electrode 5 disposed around the article closely to its external surface so that the plasma is generated only on the inner surface of the article 8.

In some embodiment, argon plasma treatment is made on the inner surface of the 3D article. Preferentially, the argon plasma treatment is between 1 and 20s, more preferentially between 5 and 10s.

In some embodiment, the argon plasma treatment increases the energy on the surface in order to obtain a better adherence on it of a plasma deposition.

In some embodiment, a first plasma deposit is made on the plasma treated inner surface of the article, using tetramethylsilane Si—(CH₃)₄ and oxygen O₂ both injected at a given flow rate in said internal volume of the article forming the reaction chamber. Preferentially, power is loaded to the plasma by radiofrequency, the frequency being of 13.56 MHz. The ratio between oxygen and tetramethylsilane is between zero and three in the vacuum chamber and the treatment time is between one to four seconds.

In some embodiment, the tetramethylsilane has a saturation vapor pressure of around 900 mbar at ambient temperature and does not need to be added in a carrier gas in order to be moved from a storage place to the reacting chamber 9.

In some embodiment, it is not necessary to heat the gas during the process according to the invention, and more precisely during the moving between the storage place of the gas and the reacting chamber in order to avoid the condensation of the gas.

In some embodiment, the first deposit is a first SiOxCyHz layer (or coating) of a few nanometers thick, the thickness of said first SiOxCyHz coating is from about 0.1 nanometer to about 15 nanometers.

In some embodiment, the chemical composition of this first SiOxCyHz coating is the following:
a. Si: 27.6%
b. O: 43.6%
c. C: 17.1%
d. H: 11.7%

Formula SiOxCyHz x being 1.58, y being 0.62 and z being 0.42.

In some embodiment, the second plasma deposit is then made on the coated inner surface of the article, using tetramethylsilane and oxygen again. Power is again loaded by RF, same frequency being used. The ratio between oxygen and tetramethylsilane in said internal volume of the article forming the reaction chamber is maintained between four and ten, i.e. the oxygen flow rate in said internal volume is between four and ten times bigger than the tetramethylsilane flow rate in said internal volume and the treatment time is between five to thirty seconds. Preferentially, the ratio between oxygen and tetramethylsilane is between four and seven.

In some embodiment, the second deposit is a SiOxCyHz layer (or coating) of a few nanometers thick. More precisely, the thickness of said second SiOxCyHz coating is from about 10 nanometers to about 100 nanometers, preferentially from 15 to 50 nanometers, and more preferentially around 30 nanometers.

In some embodiment, the chemical composition of this second SiOxCyHz coating is the following (ESCA, FTIR and ERD analyses):
a. Si: 28.5%
b. O: 50.55%
c. C: 12.55%
d. H: 8.35%

Formula SiOxCyHz x being 1.77, y being 0.44 and z being 0.29

In some embodiment, the chemical composition of this second SiOxCyHz coating is the following (ESCA, FTIR and ERD analyses):
a. Si: 28.75%
b. O: 54.95%
c. C: 8.9%
d. H: 7.4%

Formula SiOxCyHz x being 1.91, y being 0.31 and z being 0.257.

In some embodiment, after the second deposit of the second SiOxCyHz coating, the reduced atmosphere is increased to the ambient atmosphere.

In some embodiment, the method for manufacturing a polymer article having a thin coating formed on at least one of its side by plasma according to the present invention comprises successively:
a. a plasma treatment on said polymer article, advantageously an argon plasma treatment;
b. a deposition of a first coating of SiOxCyHz by generation of a plasma from tetramethylsilane, preferentially in the presence of an oxidizing gas, preferentially oxygen 02 or carbon dioxyde, the x value being between 0 and 1.7, the y value being between 0.5 and 0.8, the z value being between

0.35 and 0.6 for said first SiOxCyHz coating, and
c. a subsequent deposition of a second coating of SiOxCyHz by generation of a plasma from tetramethylsilane in the presence of an oxidizing gas, preferentially oxygen 02 or carbon dioxide, the x value being between 1.7 and 1.99, the y value being between 0.2 and 0.7, the z value being between 0.2 and 0.35 for said second SiOxCyHz coating, the thickness of said first coating being from about 1 nanometer to about 15 nanometers and the thickness of said second coating being from about 10 nanometers to about 100 nanometers, preferentially around 30 nanometers.

In some embodiment, the polymer article is configured in the form of a article, its inner side being plasma treated and coated.

In some embodiment, when the polymer article is an article having an internal volume, the method according the invention comprises before said step of plasma treatment on said polymer article, the following steps of: placing a polymer article in a vacuum chamber; decreasing the pressure in the vacuum chamber; decreasing the pressure in the internal volume of the polymer article; applying an electrical glow discharge through an electrode disposed around the article closely to its external surface.

In some embodiment, a first coating of SiOxCyHz which is either a plasma polymerized tetramethylsilane or a plasma polymerized tetramethylsilane and an oxidizing gas, preferentially oxygen or carbon dioxide, deposited on the surface on a polymer article, with an x value between 0 and 1.7, an y value between 0.5 and 0.8, and an z value between 0.35 and 0.6 for said first SiOxCyHz coating is highly preferential and that a second coating of SiOxCyHz which is a plasma polymerized tetramethylsilane and an oxidizing gas, preferentially oxygen or carbon dioxide, deposited on the surface on the first coating, with an x value between 1.7 and 1.99, an y value between 0.2 and 0.7, and an z value between 0.2 and 0.35 for said second SiOxCyHz coating is highly preferential.

In some embodiment, the coating according to the invention may be made using either magnetic guidance, or a plasma generating electrode, or both magnetic guidance and a plasma generating electrode.

In some embodiment, the polymer article is a 3D shaped one, this article being placed in a vacuum chamber and defining an internal volume and an external volume, the inner part of the article defining the internal volume as the reacting chamber, pressure inside said reacting chamber being around 0.01 mbar.

In some embodiment, the ratio between oxygen and tetramethylsilane in the internal volume of the article forming the reaction chamber is maintained between four and ten, i.e. the oxygen flow rate in said internal volume is between four and ten times bigger than the tetramethylsilane flow rate in said internal volume and the treatment time is between five to thirty seconds. Preferentially, the ratio between oxygen and tetramethylsilane is between four and seven.

In some embodiment, the layer is a SiOxCyHz layer (or coating) of a few nanometers thick. More precisely, the thickness of said SiOxCyHz coating is from about 10 nanometers to about 100 nanometers, preferentially from 15 to 50 nanometers, and more preferentially around 30 nanometers. Nevertheless, a method with a first SiOxCyHz coating and a second SiOxCyHz coating is highly preferential and results in a polymer article with improved features (wash resistance, transparency, etc.).

In some embodiment, an initial deposit of hydrogenated amorphous carbon with acetylene gas at low pressure are brought to the plasma state, and then the creation of a second deposit of fluorinated carbon by means of a plasma of R134 (C₂H₂F₄, or H₂FCCF₃ or Tetrafluoroethane—1,1,1,2).

In some embodiment, the reactive fluids used are inert, not dangerous and inexpensive, which makes the invention very advantageous from an economic point of view.

In some embodiment, the polymer article for which it is desired to improve the hydrocarbon diffusion barrier properties is introduced into a sealed treatment chamber under vacuum.

In some embodiment, said treatment chamber is carried out by means of conventional pumping means, to a vacuum level between 0.001 mbar and 1 mbar, preferentially below 0.1 mbar.

In some embodiment, a flow of gas or gaseous mixture is introduced into said treatment chamber.

In some embodiment, the pressure inside the treatment chamber is increased to values between 0.002 mbar and 10 mbar, the flow rate preferably being chosen to attain a pressure below 1 mbar but above 0.01 mbar.

In some embodiment, the gas or gaseous mixture is released in proximity to the polymer surface which has been introduced into the treatment chamber that will be called the treatment zone.

In some embodiment, electrical or electromagnetic energy in the treatment zone is applied by means of specific generation and transport means for said energy, which generally has the effect of bringing the gas or gaseous mixture to the plasma state if certain conditions of pressure and power density of the energy are met.

In some embodiment, the energies used for the creation of said plasma may be derived from a direct current voltage (DC), from a high frequency (HF), from a radiofrequency (13.46 MHz and its harmonics for example) or from microwaves (915 MHz, 2,450 MHZ).

In some embodiment, the space densities of power that are implemented are between 0.01 W/cm³ and 10 W/cm³, but preferentially between 0.1 W/cm³ and 3 W/cm³.

In some embodiment, the frequencies preferentially used are those, industrial, of 40 kHz, 13.56 MHz and 2,450 MHz.

In some embodiment, the plasma state then has the effect of bringing said gas or gaseous mixture to a state of partial ionization.

In some embodiment, the particles derived from these excitation and decomposition mechanisms may then either recombine among themselves to result in more-or-less unstable particles which may then condense on the polymer surface which is immersed in this plasma mixture, or likewise condense on the polymer surface.

In some embodiment, before bringing the chamber back to atmospheric pressure, a second deposit cycle is carried out by reproduction according to the cycle described previously from a new gas or gaseous mixture.

In some embodiment, several cycles are carried out with different gases or gaseous mixtures thus making it possible to coat the polymer surface with as many layers.

In some embodiment, the first cycle may be a step for preparation of the polymer surface which consists in “chemically cleaning” said polymer surface.

In some embodiment, a preparation of the polymer surface is conducted by using, preferentially, a plasma of argon or argon+hydrogen mixture.

In some embodiment, the pressure conditions are then between 0.01 mbar and 5 mbar, but preferentially between 0.05 mbar and 1 mbar.

In some embodiment, the plasma preparation times are generally between 1 second and 30 seconds according to the nature of the polymer surface to be prepared.

In some embodiment, there are two types of sub-layers: a first sublayer of hydrogenated amorphous carbon and a second sub-layer of fluorinated amorphous carbon.

In some embodiment, the first sub-layer of hydrogenated amorphous carbon is created from acetylene gas whose beneficial distinctive characteristic is a more-or-less significant fall in the pressure when this gas is put in a plasma state thereby promoting the obtaining of a more homogenous deposit.

In some embodiment, the second sub-layer of fluorinated amorphous carbon is created from the precursor gas R134 with chemical formula C₂F₄H₂ or from precursor gas R125 with chemical formula C₂F₅H according to the application.

In some embodiment, rigid articles made of High Density Polyethylene (PEHD) polymer, hollow and totally open, with a 0.2 liter capacity were coated with the plasma.

In some embodiment, rigid articles is placed in a metallic treatment chamber of cylindrical shape connected to a microwave emission device emitting at 2,450 MHz with standard waveguide means with standard dimensions.

In some embodiment, the device creates a differential pressure between the internal volume of the article and the external volume in such a way that the outside pressure is greater than the internal pressure. In this way, if the external pressure is sufficiently great, the plasma generation occurs solely inside the article and the deposit is then created on the internal wall of the latter.

In some embodiment, the pumping circuit is connected up with the treatment chamber and with the internal volume of the polymer article. In some embodiment, a vacuum is created by means of a standard primary vacuum pump. In some embodiment, the pressure inside the article is brought back to a pressure less than 0.05 mbar while the pressure on the outside is maintained at approximately 30 mbar.

In some embodiment, a flow of a mixture of argon and hydrogen gases is introduced into the article in the proportions of 90/10 although this is not a requirement in order for the internal pressure to attain a value between 0.05 and 1 mbar.

In some embodiment, microwave energy is applied at a power of approximately 200 W, which makes possible the creation of a surface preparation plasma maintained for a duration of 6 seconds. After this time, the microwave energy and the gas mixture flow are cut off.

In some embodiment, an acetylene gas flow is introduced into the article in such a way that the internal pressure attains a value between 0.05 and 0.3 mbar. Microwave energy is then applied at a power of approximately 300 W, which makes possible the creation of a deposit plasma maintained for a duration of one second.

In some embodiment, after microwave energy and the gas flow are cut off, an R134 gas flow is introduced into the article in such a way that the internal pressure attains a value between 0.05 and 0.3 mbar.

In some embodiment, microwave energy is applied at a power of approximately 300 W, which makes possible the creation of a deposit plasma maintained for a duration of six seconds. After this time, the microwave energy and gas flow are cut off.

In some embodiment, the pumping circuit is isolated from the treatment chamber and from the internal volume of the polymer article. In some embodiment, the treatment chamber and the polymer article are brought back to atmospheric pressure.

Each embodiment disclosed herein is contemplated as being applicable to each of the other disclosed embodiments. Thus, all combinations of the various elements described herein are within the scope of the invention. In addition, when lists are provided, the list is to be considered as a disclosure of any one member of the list.

This invention will be better understood by reference to the Experimental Details which follow, but those skilled in the art will readily appreciate that the specific experiments detailed are only illustrative of the invention as described more fully in the claims which follow thereafter. The invention is illustrated by the following examples without limiting it thereby.

### EXPERIMENTAL DETAILS

### Example 1

An experiment was conducted to evaluate acetophenone release in the plasma treated bottles. Mavrik® jet formulation was packed in different type of bottles supplied by Delta Engineering, sealed with induction sealing and packed secondarily in a closed LDPE bag. The plasma treated bottle is produced at Reyde from the Armando Alvarez group (1 L volume). Bottles within the bag was incubated in a heat storage and after storage time, the acetophenone released from bottle was analytically measured to compare the comparative acetophenone release form various type of bottles. Plasma treated bottles showed ⅙th to 1/7th of acetophenone release after 11 days storage at 54° C.

| | | | | | Average. |
|---|---|---|---|---|---|
| Bottle | Fill volume | Storage | | Acetophenone | peak area |
| No. | (mL), Planned | space | Type packing | Area | (GC) |
| 1 | 10000 | Oven 54° C. | Plasma Coated | 2125 | 2126 |
| 2 | 10000 | Oven 54° C. | Plasma Coated | 2127 | |
| 4 | 10000 | Oven 54° C. | Co-eX PA | 16215 | 14772 |
| 5 | 10000 | Oven 54° C. | Co-eX PA | 13329 | |
| 6 | 10000 | Oven 54° C. | HDPE | 13169 | 13169 |

### Example 2

An experiment was conducted to evaluate acetophenone release in Prothioconazole 250 EC formulation in the plasma treated bottles supplied by Delta Engineering. The plasma treated bottle is produced at Reyde from the Armando Alvarez group (IL volume). Prothioconazole 250 EC formulation was packed in different type of bottles, sealed with induction sealing and packed secondarily in a closed LDPE bag for about 10-11 days. Bottles within the bag was incubated in a heat storage and after storage time, the acetophenone from bottle was analytically measured to compare the comparative acetophenone form various types of bottles.

Prothioconazole 250 EC

| Fill volume | Storage | | | Acetophenone |
|---|---|---|---|---|
| (mL), Planned | space | Type packing | Comments | Area |
| 1000 | Oven 54° C. | Co-Ex-PA Black | label no color | 1553 |
| | | inner layer 2.5%, | change, very little | |
| | | | smell | |
| 1000 | Oven 54° C. | Plasma bottle | label no color | 743 |
| | | | change, very little | |
| | | | smell | |

### Example 3

An experiment was conducted to evaluate acetophenone release in Abamectin 18 EW formulation in the plasma treated bottles supplied by Delta Engineering. The plasma treated bottle is produced at Reyde from the Armando Alvarez group (1 L volume). Abamectin 18 EW formulation was packed in different type of bottles, sealed with induction sealing and packed secondarily in a closed LDPE bag for about 10-11 days. Bottles within the bag was incubated in a heat storage and after storage time, the acetophenone released from bottle was analytically measured to compare the comparative acetophenone release form various types of bottles.

Abamectin 18 EW

| Fill volume | Storage | | | |
|---|---|---|---|---|
| (mL), Planned | space | Type packing | Comments | Acetophenone Area |
| 1000 | Oven 54° C. | Co-Ex-PA | low | 14.3 |
| | | | discoloration of | |
| | | | label- | |
| | | | blackening | |
| 1000 | Oven 54° C. | Plasma bottle | No discoloration | 8.81 |

### Example 4

An experiment was conducted to evaluate acetophenone release in the plasma treated bottles. Abamectin 18 EW formulation was packed in different type of bottles, sealed with induction sealing and packed secondarily in a closed LDPE bag. Bottles within the bag was incubated in a heat storage and after storage time, the acetophenone released from bottle was analytically measured to compare the comparative acetophenone release form various type of bottles. Plasma treated bottles showed ⅓rd of acetophenone release after 14 days storage at 54° C.

| | Fill | | | |
|---|---|---|---|---|
| Bottle | volume | Storage | | acetophenone |
| No. | (mL) | space | Type of packing | Area (GC) |
| 1 | 1000 | Room, 2 W | HDPE Plasma with aluminum | Not detected |
| | | | pouch | |
| 2 | 1000 | Room, 2 W | HDPE Plasma with aluminum | Not detected |
| | | | pouch | |
| 3 | 1000 | Room, 2 W | HDPE Plasma with aluminum | Not detected |
| | | | pouch | |
| 4 | 1000 | Room, 2 W | Co-Ex-PA with aluminum pouch | Not detected |
| 5 | 1000 | Room, 2 W | Co-Ex-PA with aluminum pouch | Not detected |
| 6 | 1000 | Room, 2 W | Co-Ex-PA with aluminum pouch | Not detected |
| 7 | 1000 | Oven 54° C., | HDPE Plasma with aluminum | 6622 |
| | | 2 W | pouch | |
| 8 | 1000 | Oven 54° C., | HDPE Plasma with aluminum | 5876 |
| | | 2 W | pouch | |
| 9 | 1000 | Oven 54° C., | HDPE Plasma with aluminum | 6174 |
| | | 2 W | pouch | |
| 10 | 1000 | Oven 54° C., | Co-Ex-PA with aluminum pouch | 18005 |
| | | 2 W | | |
| 11 | 1000 | Oven 54° C., | Co-Ex-PA with aluminum pouch | 17889 |
| | | 2 W | | |
| 12 | 1000 | Oven 54° C., | Co-Ex-PA with aluminum pouch | 18778 |
| | | 2 W | | |

1. A method of preventing leakage of an aromatic compound from an article containing a formulation comprising an aromatic compound and a polar liquid or a non-polar liquid, wherein the method comprises plasma-coating the article.

2. The method of claim 1, wherein the formulation comprising the aromatic compound and the polar liquid is an emulsion-in-water (EW) formulation, or wherein the formulation comprising the aromatic compound and the non-polar liquid is an emulsifiable-concentrate (EC) formulation and is optionally mixed with a polar liquid as a co-solvent; or wherein the plasma is one or more of tetrafluoroethane-1, 1, 1, 2, argon, acetylene, pentafluoroethane, difluoromethane or SiOxCyHz, wherein x is between 0 and 1.7, y is between 0.5 and 0.8, and z is between 0.35 and 0.6, preferably, the plasma is tetrafluoroethane-1, 1, 1, 2, or pentafluoroethane.

3. The method of claim 2, wherein the EW formulation further comprising the aromatic compound with macrocyclic lactones endectocides, preferably, the macrocyclic lactones endectocides is abamectin, doramectin, eprinomectin, ivermectin, milbemycin, moxidectin, or selamectin, more preferably, the macrocyclic lactones endectocides is abamectin; or wherein the plasma is SiOₓC_{y}H_{z}, wherein x is between 0 and 1.7, y is between 0.5 and 0.8, and z is between 0.35 and 0.6, preferably, x is between 1.7 and 1.99, y is between 0.2 and 0.7, and z is between 0.2 and 0.35.

4. (canceled)

5. (canceled)

6. The method of claim 2, wherein the formulation comprises the aromatic compound with a triazole fungicide with a non-polar liquid and is optionally mixed with a polar liquid as a co-solvent, wherein
a) the triazole fungicide is cyproconazole, flusilazole, flutriafol, metconazole, myclobutanil, propiconazole, prothioconazole, tebuconazole, or tetraconazole; more preferably, the triazole fungicide is prothioconazole;
b) the non-polar liquid is Aromatic solvent C10 (Solvesso™ 150), Solvent Naphtha (Petroleum), Light Aromatic (Solvesso™ 100), Aromatic solvent C12 (Solvesso™ 200), cyclohexanone, isophorone, methyl ethyl ketone, methyl iso butyl ketone, acetophenone, xylene, methyl soyate, Rapeseed oil methyl ester (Agnique® ME 18RD-F), paraffinic oils, rapeseed oil, soybean oil, dimethylamide based on naturally derived fatty acids (Genagen® 4296), 2-ethylhexyl-1-lactate (Purasolv® EHL), dimethylamide based on naturally derived fatty acids (Genegen® 4166), unsaturated di-substituted amide (Steptosol® MET10U), C8-10 Methyl Caprylate-Caprate (Agnique® ME 610-G), N-octyl pyrrolidone (Agsolex™-8), or N-dodecyl pyrrolidone (Agsolex™-12),
c) the polar liquid is water, methyl 5-(dimethylamino)-2-methyl-5-oxopentanoate (Rhodiasolv® Polar Clean), N, N-dimethyl lactamide (Agnique® AMD 3 L), morpholine/carbonate blend (Armid™ FMPC), propylene carbonate, n-butylpyrrolidone, (Genagen NBP™), DMSO, DMF, NMP, ethyl lactate, PEG 200, butyrolactone, THFA, propylene glycol, butanol, dipropylene glycol, or methyl lactate; or
d) the aromatic compound is an aromatic ketone, preferably the aromatic compound is selected from a group consisting of 3′,5′-dimethoxyacetophenone, raspberry ketone, acetophenone, benzophenone, 4′-methylacetophenone, benzylacetone, 4-(4-methoxyphenyl)-2-butanone, piperonyl acetone, 4′-methoxyacetophenone, dimedone, thenoyltrifluoroacetone, 4′-fluoropropiophenone, 1,3-diphenylacetone, n-(2-benzoyl-4-chlorophenyl)-2-chloro-n-methylacetamide, 4-chlorophenylacetone, 4-hydroxyphenylacetone, 4′-bromo-3′-nitroacetophenone, cyclopentyl phenyl ketone, (+)-pulegone, 4,4-diphenyl-2-butanone, 3,4-dihydroxyphenylacetone, (3-(trifluoromethoxy)phenyl) acetone, 4′-chloro-2 phenylacetophenone, 4-hydroxy-3-methoxyphenylacetone, 3-tetradecanone, 4-(4-hydroxy-3-methoxyphenyl)-3-buten-2-one, indole-3-acetone, 2-chloro-6-fluorophenylacetone, 3,4-(methylenedioxy) benzylideneacetone, 4′-aminobutyrophenone, 4-ethylphenylacetone, 4′-methyl-2-phenylacetophenone, n-tetradecanophenone, 4′-methoxy-2-phenylacetophenone, 2,6-dichlorophenylacetone, 2, 5-dimethylphenylacetone, zearalenone, 3,4,5-trimethoxyphenylacetone, 14-heptacosanone, 2-bromo-1-(3-bromophenyl)-1-propanone, nootkatone(sg), 4-methylphenylacetone, piperonyl methyl ketone, 10-nonadecanone, (4-carboxyphenyl) acetone, 4,4′-dibromobenzil, 3-methylphenylacetone, 4-hydroxybenzylideneacetone, 4-nitrophenylacetone, 3-chlorophenylacetone, 2,6-difluorophenylacetone, 3-methoxyphenylacetone, 1-acetamido-acetone, 1,3-dibromoacetone, (2, 4-dimethoxyphenyl) acetone, and any combination thereof; or
wherein plasma coating the article comprises
a) depositing a first deposit layer with a discharge plasma in acetylene gas at low pressure; and
b) depositing a second deposit layer with a discharge plasma in at least one of tetrafluoroethane-1, 1, 1, 2 or pentafluoroethane precursor gas,
preferably, depositing the first deposit layer and the second deposit layer comprises:
i) introducing the article made of polymer material into a treatment chamber;
ii) introducing at least one precursor gas into the treatment chamber; and
iii) applying one of electrical energy or electromagnetic energy of a sufficient space density power and a sufficient frequency to bring the at least one gas to a plasma state; and subjecting the article made of polymer material to the plasma state for a sufficient plasma phase time so as to deposit one of the first deposit layer or second deposit layer.

7. The method of claim 1, wherein the aromatic compound has the following structure: 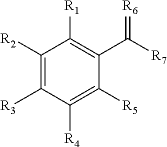
wherein R₁, R₂, R₃, R₄, and R₅ are each independently hydrogen, C₁₋₆ alkyl, C₁₋₆ alkoxy, phenyl, benzyl, or halogen; wherein Re is O or S; and
wherein R₇ is hydrogen, CH₂NO₂, C₁₋₆ alkyl, C₁₋₆ alkoxy, phenyl, benzyl, or halogen; preferably, the aromatic compound is acetophenone; or
wherein plasma coating the article further comprising applying the electrical or electromagnetic energy such that the space density of power is in a range from about 0.01 W/cm³ to about 10 W/cm³, preferably, the space density of power is in a range from about 0.1 W/cm³ to about 3 W/cm³; or
wherein the polymer article comprising:
a) a thin coating on at least one side of said article;
b) a polymer material defining a supporting surface of the polymer article;
c) wherein said thin coating directly covers the supporting surface;
preferably, said thin coating comprises an outer coating of SiOₓC_{y}H_{z} defining an outer surface of the polymer article, the outer coating of SiOₓC_{y}H_{z} being a plasma polymerized tetramethylsilane and an oxidizing gas, wherein x is between 1.7 and 1.99, y is between 0.2 and 0.7, and z is between 0.2 and 0.35, for said outer SiOₓC_{y}H_{z} coating; preferably,
(a) the thickness of said outer coating is from about 10 nanometers to about 100 nanometers; preferably, wherein said thin coating comprises a first coating of SiOₓC_{y}H_{z} which is either a plasma polymerized tetramethylsilane or a plasma polymerized tetramethylsilane and an oxidizing gas, deposited on the supporting surface on said polymer article, and wherein the outer coating of SiOₓC_{y}H_{z} is a second coating of SiOₓC_{y}H_{z} deposited on the surface on said first coating;
(b) x is between 0 and 1.7, y is between 0.5 and 0.8, and z is between 0.35 and 0.6 for said first SiOₓC_{y}H_{z} coating, the first coating and the second coating defining said thin coating;
(c) the thickness of said first coating is from about 1 nanometer to about 15 nanometers, or wherein a thickness of said second coating is from 15 nanometers to 50 nanometers, preferably 30 nanometers;
(d) the value of x for said first SiOₓC_{y}H_{z} coating is less than a value of x for said second SiOₓC_{y}H_{z} coating, and a value of z for said first SiOₓC_{y}H_{z} coating is greater than a value of z for said second SiOₓC_{y}H_{z} coating; or
(e) the supporting surface is an inner surface of a three-dimensional article, or wherein said outer coating defines the thin coating and is directly deposited on said supporting surface.

8. The method of claim 1, wherein
a) the formulation comprises from about 10% to about 40% by weight of aromatic compound based on the total weight of the formulation; preferably, the formulation comprises from about 20% to about 30% by weight of aromatic compound based on the total weight of the formulation, more preferably, the formulation comprises about 208 by weight of aromatic compound based on the total weight of the formulation;
b) the formulation comprising aromatic compound is stored in the plasma coated article for a period over 8-15 days; preferably the formulation comprising aromatic compound is stored in the plasma coated article for a period over 11 days; and/or
c) the formulation comprising aromatic compound is stored at about 25-70° C., preferably, the formulation comprising aromatic compound is stored at about 40-65° C., more preferably, the formulation of aromatic compound is stored at about 52-60° C., most preferably, the formulation of aromatic compound is stored at about 54° C.; or
wherein plasma coating the article further comprises
a) selecting the frequency from the group consisting of 40 kHz, 13.56 MHz, and 2,450 MHZ;
b) maintaining the plasma phase for a time in a range from about 1 second to about 2 minutes, preferably, the plasma phase was maintained for a time in a range from about 1 second to about 30 seconds; or
c) introducing the at least one precursor gas into the treatment chamber at a flow rate such that a pressure inside the treatment chamber is in a range from about 0.002 mbar to about 10 mbar, preferably, the pressure inside the treatment chamber is in a range from about 0.01 mbar to about 1 mbar.

9. The method of claim 8 for preventing leakage, such that after storing the formulation comprising aromatic compound in the plasma coated article for 11 days at 54° C., more than 80% by weight of the acetophenone remain in the formulation, preferably, more than 85% by weight of the aromatic compound remain in the formulation, more preferably, more than 90% by weight of the aromatic compound remain in the formulation, more preferably, more than 95% by weight of the aromatic compound remain in the formulation, most preferably, more than 99% by weight of the aromatic compound remain in the formulation; or
wherein plasma coating the article further comprises a preparation step comprising:
a) preparing at least one surface of the article made of polymer material prior to depositing the first and second deposit layers, the method of preparing comprising implementing a low-pressure discharge plasma in at least one gas selected from the group consisting of oxygen, hydrogen, argon, carbon dioxide, helium, nitrogen, and combinations thereof by:
i) introducing the at least one gas into the treatment chamber; preferably, implementing a low-pressure discharge plasma from a mixture of argon and hydrogen, with a pressure in a range from about 0.01 mbar to about 5 mbar, or preferably, the low-pressure discharge plasma from the mixture of argon and hydrogen is in a range from about 0.05 mbar to about 1 mbar;
ii) applying one of electrical energy or electromagnetic energy of a sufficient space density power and a sufficient frequency to bring the at least one gas to a plasma state; and subjecting the article made of polymer material to the plasma state for a sufficient plasma phase time to prepare the at least one surface; preferably, the electrical or electromagnetic energy is in a range from about 0.01 W/cm³ to about 10 W/cm³ preferably, the space density of power is in a range from about 0.1 W/cm³ to about 3 W/cm³;
optionally comprising maintaining the plasma phase for a time in a range from about one second to about thirty second, or, further comprising: depositing a third deposit layer with a low-pressure discharge plasma in acetylene or pentafluoroethane gas.

10. The method of claim 6, wherein the article is made of polymer materials selected from a group consisting of polyethylene, high-density polyethylene (HDPE), polypropylene, polyamide, PET, vinyl polychloride, polycarbonate, poly butyl teraphtalate, and a combination thereof; or
wherein the article is made of polymer material comprises a substantially open hollow article of high-density polyethylene and wherein the internal pressure within the article is less than about 0.05 mbar and the external pressure is about 30 mbar, and wherein the precursor comprises a mixture of argon and hydrogen gases, the method further comprising:
(a) introducing the mixture of argon and hydrogen gas within the treatment chamber at a flow rate such that the internal pressure is in a range of about 0.05 and 1 mbar;
(b) applying microwave energy with a power of about 200 W to form a plasma;
(c) subjecting the article to the plasma for a duration of about 6 seconds; and
(d) turning off the microwave energy and the flow of the mixture of argon and hydrogen gas; or
wherein depositing a first deposit layer with a discharge plasma in acetylene gas at low pressure comprises:
(a) introducing the acetylene gas to the treatment chamber at a flow rate such that the internal pressure is in a range of about 0.05 and 0.3 mbar;
(b) applying microwave energy with a power of about 300 W to form a plasma;
(c) subjecting the article to the plasma for a duration of about 1 second;
(d) and turning off the microwave energy and the flow of the acetylene gas; or
wherein depositing a second deposit layer with a discharge plasma in at least one of tetrafluoroethane-1, 1, 1, 2 or pentafluoroethane precursor gas comprises:
(a) introducing the acetylene gas to the treatment chamber at a flow rate such that the internal pressure is in a range of about 0.05 and 0.3 mbar;
(b) applying microwave energy with a power of about 300 W to form a plasma;
(c) subjecting the article to the plasma for a duration of about 6 seconds; and
(d) turning off the microwave energy and the flow of the precursor gas.

11.-22. (canceled)

23. A plasma-coated article containing a formulation comprising an aromatic compound and a polar liquid or a non-polar liquid.

24. The article of claim 23, wherein the formulation comprising the aromatic compound and the polar liquid s an emulsion-in-water (EW) formulation; or wherein the formulation comprising the aromatic compound and the non-polar liquid is an emulsifiable-concentrate (EC) formulation and is optionally mixed with a polar liquid as a co-solvent; or wherein the plasma is one or more of tetrafluoroethane-1, 1, 1, 2, argon, acetylene, pentafluoroethane, difluoromethane or SiOxCyHz, wherein x is between 0 and 1.7, y is between 0.5 and 0.8, and z is between 0.35 and 0.6, preferably, the plasma tetrafluoroethane-1, 1, 1, 2, or pentafluoroethane.

25. The article of claim 24, wherein the formulation comprises the aromatic compound with macrocyclic lactones endectocides, preferably, endectocides is abamectin, doramectin, eprinomectin, macrocyclic lactones ivermectin, milbemycin, moxidectin, or selamectin, more preferably, the macrocyclic lactones endectocides is abamectin; or wherein the plasma is SiOₓC_{y}H_{z}, wherein x is between 0 and 1.7, y is between 0.5 and 0.8, and z is between 0.35 and 0.6, preferably, x is between 1.7 and 1.99, y is between 0.2 and 0.7, and z is between 0.2 and 0.35.

26. (canceled)

27. (canceled)

28. The article of claim 23, wherein the formulation comprises the aromatic compound with a triazole fungicide with a non-polar liquid and is optionally mixed with a polar liquid as a co-solvent, wherein
a) the triazole fungicide is cyproconazole, flusilazole, flutriafol, metconazole, myclobutanil, propiconazole, prothioconazole, tebuconazole, or tetraconazole; more preferably, the triazole fungicide is prothioconazole;
b) the non-polar liquid is Aromatic solvent C10 (Solvesso™ 150), Solvent Naphtha (Petroleum), Light Aromatic (Solvesso™ 100), Aromatic solvent C12 (Solvesso™ 200), cyclohexanone, isophorone, methyl ethyl ketone, methyl iso butyl ketone, acetophenone, xylene, methyl soyate, Rapeseed oil methyl ester (Agnique® ME 18RD-F), paraffinic oils, rapeseed oil, soybean oil, dimethylamide based on naturally derived fatty acids (Genagen® 4296), 2-ethylhexyl-1-lactate (Purasolv® EHL), dimethylamide based on naturally derived fatty acids (Genegen® 4166), unsaturated di-substituted amide (Steptosol® MET10U), C8-10 Methyl Caprylate-Caprate (Agnique® ME 610-G), N-octyl pyrrolidone (Agsolex™-8), or N-dodecyl pyrrolidone (Agsolex™-12);
c) the polar liquid is water, methyl 5-(dimethylamino)-2-methyl-5-oxopentanoate (Rhodiasolv® Polar Clean), N, N-dimethyl lactamide (Agnique® AMD 3 L), morpholine/carbonate blend (Armid™ FMPC), propylene carbonate, n-butylpyrrolidone, (Genagen NBP™), DMSO, DMF, NMP, ethyl lactate, PEG 200, butyrolactone, THFA, propylene glycol, butanol, dipropylene glycol, or methyl lactate; or
d) the aromatic compound is an aromatic ketone, preferably the aromatic compound is selected from a group consisting of 3′,5′-dimethoxyacetophenone, raspberry ketone, acetophenone, benzophenone, 4′-methylacetophenone, benzylacetone, 4-(4-methoxyphenyl)-2-butanone, piperonyl acetone, 4′-methoxyacetophenone, dimedone, thenoyltrifluoroacetone, 4′-fluoropropiophenone 1,3-diphenylacetone, n-(2-benzoyl-4-methylacetamide, chlorophenyl)-2-chloro-n-4-chlorophenylacetone, 4-hydroxyphenylacetone, 4′-bromo-3′-nitroacetophenone, cyclopentyl phenyl ketone, (+)-pulegone, 4,4-diphenyl-2-butanone, 3,4-dihydroxyphenylacetone, (3-(trifluoromethoxy)phenyl) acetone, 4′-chloro-2-phenylacetophenone, 4-hydroxy-3-methoxyphenylacetone, 3-tetradecanone, 4-(4-hydroxy-3-methoxyphenyl)-3-buten-2-one, indole-3-acetone, 2-chloro-6-fluorophenylacetone, 3,4-(methylenedioxy) benzylideneacetone, 4′-aminobutyrophenone, 4-ethylphenylacetone, 4′-methyl-2-phenylacetophenone, n-tetradecanophenone, 4′-methoxy-2-phenylacetophenone, 2,6-dichlorophenylacetone, 2, 5-dimethylphenylacetone, zearalenone, 3,4,5-trimethoxyphenylacetone, 14-heptacosanone, 2-bromo-1-(3-bromophenyl)-1-propanone, nootkatone (sg), 4-methylphenylacetone, piperonyl methyl ketone, 10-nonadecanone, (4-carboxyphenyl) acetone, 4,4′-dibromobenzil, 3-methylphenylacetone, hydroxybenzylideneacetone, 4-nitrophenylacetone, 3-chlorophenylacetone, 2,6-difluorophenylacetone, 3-methoxyphenylacetone, 1-acetamido-acetone, 1,3-dibromoacetone, (2, 4-dimethoxyphenyl) acetone, and any combination thereof; or
wherein plasma coating the article comprises
a) depositing a first deposit layer with a discharge plasma in acetylene gas at low pressure; and
b) depositing a second deposit layer with a discharge plasma in at least one of tetrafluoroethane-1, 1, 1, 2 or pentafluoroethane precursor gas,
preferably, depositing the first deposit layer and the second deposit layer comprises:
i) introducing the article made of polymer material into a treatment chamber;
ii) introducing at least one precursor gas into the treatment chamber; and
iii) applying one of electrical energy or electromagnetic energy of a sufficient space density power and a sufficient frequency to bring the at least one gas to a plasma state; and subjecting the article made of polymer material to the plasma state for a sufficient plasma phase time so as to deposit one of the first deposit layer or second deposit layer.

29. The article of claim 23, wherein the aromatic compound has the following structure: 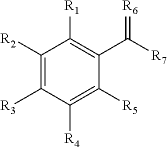
wherein R₁, R₂, R₃, R₄, and R₅ are each independently hydrogen, C₁₋₆ alkyl, C₁₋₆ alkoxy, phenyl, benzyl, or halogen; wherein R₆ is O or S; and
wherein R₇ is each hydrogen, CH NO₂, C₁₋₆ alkyl, C₁₋₆ alkoxy, phenyl, benzyl, or halogen; preferably, the aromatic compound is acetophenone; or
wherein plasma coating the article further comprising applying the electrical or electromagnetic energy such that the space density of power is in a range from about 0.01 W/cm to about 10 W/cm³, preferably, the space density of power is in a range from about 0.1 W/cm to about 3 W/cm³; or
wherein the polymer article comprising:
a) a thin coating on at least one side of said article;
b) a polymer material defining a supporting surface of the polymer article;
c) wherein said thin coating directly covers the supporting surface;
wherein said thin coating comprises an outer coating of SiOₓC_{y}H_{z} defining an outer surface of the polymer article, the outer coating of SiOₓC_{y}H_{z} being a plasma polymerized tetramethylsilane and an oxidizing gas, wherein x is between 1.7 and 1.99, y is between 0.2 and 0.7, and z is between 0.2 and 0.35, for said outer SiOₓC_{y}H_{z} coating; preferably,
(a) the thickness of said outer coating is from about 10 nanometers to about 100 nanometers; preferably, wherein said thin coating comprises a first coating of SiOₓC_{y}H_{z} which is either a plasma polymerized tetramethylsilane or a plasma polymerized tetramethylsilane and an oxidizing gas, deposited on the supporting surface on said polymer article, and wherein the outer coating of SiOₓC_{y}H_{z} is a second coating of SiOₓC_{y}H_{z} deposited on the surface on said first coating;
(b) x is between 0 and 1.7, y is between 0.5 and 0.8, and z is between 0.35 and 0.6 for said first SiOₓC_{y}H_{z} coating, the first coating and the second coating defining said thin coating;
(c) the thickness of said first coating is from about 1 nanometer to about 15 nanometers, or wherein a thickness of said second coating is from 15 nanometers to 50 nanometers, preferably 30 nanometers;
(d) the value of x for said first SiOₓC_{y}H_{z} coating is less than a value of x for said second SiOₓC_{y}H_{z} coating, and a value of z for said first SiOₓC_{y}H_{z} coating is greater than a value of z for said second SiOₓC_{y}H_{z} coating; or
(e) the supporting surface is an inner surface of a three-dimensional article, or wherein said outer coating defines the thin coating and is directly deposited on said supporting surface.

30. The article of claim 23, wherein
(a) the formulation comprises from about 10% to about 40% by weight of aromatic compound based on the total weight of the formulation; preferably, the formulation comprises from about 20% to about 30% by weight of aromatic compound based on the total weight of the formulation, more preferably, the formulation comprises about 208 by weight of aromatic compound based on the total weight of the formulation;
(b) the formulation comprising the aromatic compound is stored in the plasma coated article for a period over 8-15 days; preferably the formulation comprising aromatic compound is stored in the plasma coated article for a period over 11 days; and/or
(c) the formulation comprising the aromatic compound is the stored at about 25-70° C., preferably, formulation comprising aromatic compound is stored at about 40-65° C., more preferably, the formulation of aromatic compound is stored at about 52-60° C., most preferably, the formulation of aromatic compound is stored at about 54° C.; or
wherein plasma coating the article further comprises
a) selecting the frequency from the group consisting of 40 KHz, 13.56 MHZ, and 2,450 MHZ;
b) maintaining the plasma phase for a time in a range from about 1 second to about 2 minutes, preferably, the plasma phase was maintained for a time in a range from about 1 second to about 30 seconds; or
c) introducing the at least one precursor gas into the treatment chamber at a flow rate such that a pressure inside the treatment chamber is in a range from about 0.002 mbar to about 10 mbar, preferably, the pressure inside the treatment chamber is in a range from about 0.01 mbar to about 1 mbar.

31. The article of claim 23, wherein after storing the formulation comprising aromatic compound in the plasma coated article for 11 days at 54° C., more than 80% by weight of the aromatic compound remain in the formulation; preferably, more than 85% by weight of the aromatic compound remain in the formulation, more preferably, more than 90% by weight of the aromatic compound remain in the formulation, more preferably, more than 95% by weight of the aromatic compound remain in the formulation, most preferably, more than 99% by weight of the aromatic compound remain in the formulation; wherein the aromatic compound is acetophenone;
or wherein plasma coating the article further comprises a preparation step comprising:
a) preparing at least one surface of the article made of polymer material prior to depositing the first and second deposit layers, the method of preparing comprising implementing a low-pressure discharge plasma in at least one gas selected from the group consisting of oxygen, hydrogen, argon, carbon dioxide, helium, nitrogen, and combinations thereof by:
i) introducing the at least one gas into the treatment chamber; preferably, implementing a low-pressure discharge plasma from a mixture of argon and hydrogen, with a pressure in a range from about 0.01 mbar to about 5 mbar, or preferably, the low-pressure discharge plasma from the mixture of argon and hydrogen is in a range from about 0.05 mbar to about 1 mbar;
ii) applying one of electrical energy or electromagnetic energy of a sufficient space density power and a sufficient frequency to bring the at least one gas to a plasma state; and subjecting the article made of polymer material to the plasma state for a sufficient plasma phase time to prepare the at least one surface; preferably, the electrical or electromagnetic energy is in a range from about 0.01 W/cm³ to about 10 W/cm³ preferably, the space density of power is in a range from about 0.1 W/cm³ to about 3 W/cm³;
optionally comprising maintaining the plasma phase for a time in a range from about one second to about thirty second, or, further comprising: depositing a third deposit layer with a low-pressure discharge plasma in acetylene or pentafluoroethane gas.

32. The article of claim 28, wherein the article is made of polymer materials selected from a group consisting of polyethylene, high-density polyethylene (HDPE), polypropylene, polyamide, PET, vinyl polychloride, polycarbonate, poly butyl teraphtalate and a combination thereof;
or wherein the article made of polymer material comprises a substantially open hollow article of high-density polyethylene and wherein the internal pressure within the article is less than about 0.05 mbar and the external pressure is about 30 mbar, and wherein the precursor comprises a mixture of argon and hydrogen gases, the method further comprising:
(a) introducing the mixture of argon and hydrogen gas within the treatment chamber at a flow rate such that the internal pressure is in a range of about 0.05 and 1 mbar;
(b) applying microwave energy with a power of about 200 W to form a plasma;
(c) subjecting the article to the plasma for a duration of about 6 seconds; and
(d) turning off the microwave energy and the flow of the mixture of argon and hydrogen gas;
or wherein depositing a first deposit layer with a discharge plasma in acetylene gas at low pressure comprises:
(a) introducing the acetylene gas to the treatment chamber at a flow rate such that the internal pressure is in a range of about 0.05 and 0.3 mbar;
(b) applying microwave energy with a power of about 300 W to form a plasma;
(c) subjecting the article to the plasma for a duration of about 1 second; and
(d) turning off the microwave energy and the flow of the acetylene gas; or
or wherein depositing a second deposit layer with a discharge plasma in at least one of tetrafluoroethane-1, 1, 1, 2 or pentafluoroethane precursor gas comprises:
(a) introducing the acetylene gas to the treatment chamber at a flow rate such that the internal pressure is in a range of about 0.05 and 0.3 mbar;
(b) applying microwave energy with a power of about 300 W to form a plasma;
(c) subjecting the article to the plasma for a duration of about 6 seconds; and
(d) turning off the microwave energy and the flow of the precursor gas.

33.-45. (canceled)

46. A process for manufacturing the article of claim 23 which comprising plasma coating the article and filling the article with a formulation comprising an aromatic compound and a polar liquid or a non-polar liquid.

47. (canceled)

48. The method of claim 1, wherein the aromatic compound is acetophenone; and wherein
a) the article containing the formulation is stored
i) for at least 10-20 days; preferably, the article containing the formulation is stored for at least 12-18 days, more preferably, the article containing the formulation is stored for 14 days; and/or
ii) at room temperature; and/or
b) the article is HDPE Plasma with aluminum pouch or Co-Ex-PA with aluminum; or
(a) the article containing the formulation is stored
i) for at least 10-20 days, preferably, for at least 12-18 days, more preferably, the for 14 days; and/or
ii) at room temperature; and/or
(b) the article is HDPE Plasma with aluminum pouch or Co-Ex-PA with aluminum pouch Co-Ex-PA with aluminum pouch; or
(a) the article containing the formulation is stored
(i) for at least 10-20 days at a temperature of at least 45-60° C., preferably, at a temperature of at least 50-55° C., more preferably, at a temperature of at 54° C.; or
(ii) for at least 12-18 days at a temperature of at least 45-60° C. preferably, at a temperature of at least 50-55° C., more preferably, at a temperature of at 54° C.; or
(iii) for 14 days at a temperature of at least 45-60° C. preferably, at a temperature of at least 50-55° C., more preferably, at a temperature of 54° C.; and/or
(b) the article is HDPE Plasma with aluminum pouch or is Co-Ex-PA with aluminum pouch;
preferably 0% of the aromatic compound was leaked.

49. (canceled)

50. The method of claim 1, wherein
a) the article containing the formulation is stored
i) for at least 10-20 days at a temperature of at least 45-60° C.; preferably, at a temperature of at least 50-55° C., more preferably, at a temperature of at 54° C.;
ii) for at least 12-18 days at a temperature of at least 45-60° C.; preferably, at a temperature of at least 50-55° C., more preferably, at a temperature of at 54° C.;
iii) for 14 days at a temperature of at least 45-60° C.; preferably, at a temperature of at least 50-55° C., more preferably, at a temperature of at 54° C.; and/or
iv) at room temperature; and/or
b) the article is HDPE Plasma with aluminum pouch or is Co-Ex-PA with aluminum pouch.

51. The method of claim of 50, wherein more than 50% by weight of acetophenone remain in the formulation; preferably, more than 60% by weight of the aromatic compound remain in the formulation, more preferably, more than 66.6% by weight of the aromatic compound remain in the formulation.

52.-55. (canceled)
